(19) United States
(12) Patent Application Publication
(10) Pub. No.: US 2008/0195344 A1
(43) Pub. Date: Aug. 14, 2008

(54) METHOD FOR DETERMINING MEASUREMENT ERRORS IN SCATTERING PARAMETER MEASUREMENTS

(75) Inventors: Holger HEUERMANN, Breinig (DE); Andrej Rumiantsev, Dresden (DE)

Correspondence Address: HESLIN ROTHENBERG FARLEY & MESITI PC, 5 COLUMBIA CIRCLE, ALBANY, NY, 12203, US

(73) Assignee: SUSS MicroTec Test Systems GmbH, Sacka (DE)

(21) Appl. No.: 12/030,295

(22) Filed: Feb. 13, 2008

(30) Foreign Application Priority Data
Feb. 14, 2007 (DE) 10 2007 007 876.7

(51) Int. Cl. G01R 27/28

(52) U.S. Cl. 702/107

(57) ABSTRACT

In a method for determining measurement errors in scattering parameter measurements, in particular for giving the measurement accuracy of a scalar or vector network analyzer, which has n measurement ports (n≧1), on the basis of the measurements of the scattering parameters of at least one reference line with defined characteristic impedance, the characteristic impedance of the reference line is calculated and the reflection values of a one-port or two-port, realized by way of the reference line, are measured. The reflection values are renormalized to the known characteristic impedance of the reference line and the source match is calculated therefrom.

The invention relates to a method for determining measurement errors when measuring scattering parameters of electronic devices in radio frequency technology, in particular for giving the measurement accuracy of a scalar or vector network analyzer, which has n measurement ports (n≧1), on the basis of the measurements of the scattering parameters of at least one reference line with defined characteristic impedance.

### PRIOR ART

The description form which is customary in radio frequency technology of the electric behavior of electronic devices and components is effected via their scattering parameters (also S-parameters) which are increasingly treated as complex variables. They relate wave variables to one another rather than currents and voltages. This representation is particularly matched to the physical data. For the waves a₁ and a₂ traveling toward a two-port, for example, and the waves b₁ and b₂ correspondingly propagating in the opposite direction, the following relationship applies:

$$( \begin{matrix}{b}_{1} \\ {b}_{2}\end{matrix} ) = {\underbrace{( \begin{matrix}{S}_{11} & {S}_{12} \\ {S}_{21} & {S}_{22}\end{matrix} )}}_{= [ S ]} ( \begin{matrix}{a}_{1} \\ {a}_{2}\end{matrix} ) ,$$

where [S] is the scattering matrix characterizing the electronic properties of the two-port, and Sᵢⱼ is the scattering parameters describing the reflection and the transmission at the ports.

Scattering parameter measurements or S-parameter measurements of electronic devices and components as well as of active and passive radio frequency circuits and radio frequency assemblies up to antennas are carried out using vectorially measuring network analyzers, wherein the influence of the network analyzer on the measurement accuracy is in practice often negligible.

The measurement accuracy of the scattering parameter measurements is primarily determined by the calibration methods used and the associated calibration standards. However, the calibration standards often deviate in terms of real behavior from what is communicated to the calibration method as that value on which the calibration is to be based.

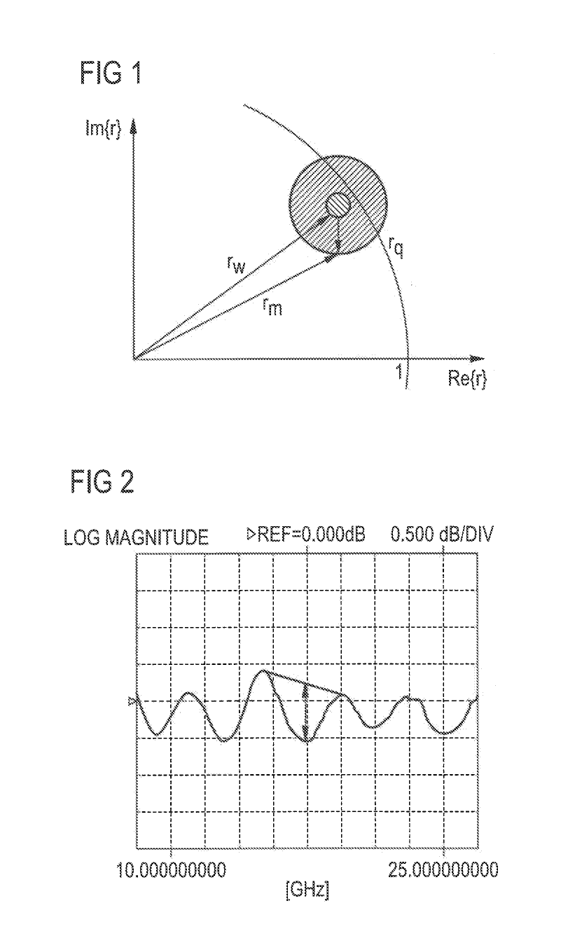

Such errors caused by the real properties of the calibration standards used are systematic measurement errors and can therefore not easily be identified by the user, as is the case with deterministic errors. Such an error results in a difference, i.e. in the case of complex parameters an error vector r_{q} between the real vector, for example of the reflection, r_{w} and the measured vector rₘ. The so-called source match, which gives the area, in which the real behavior is to be expected, in relation to the measurement result (FIG. 1), is effected by means of the error vector r_{q}.

For many years, practitioners have used the so-called “ripple test” in order to estimate the measurement accuracy. Said ripple test was introduced in the publication “Old and New Accuracy Estimation of S-Parameter Measurements with the Ripple-Test” by Holger Heuermann, MTT-S International Microwave Symposium Workshop TMB, San Francisco, June 2006.

In this ripple test, a precise line with the characteristic impedance Z₀ is measured. In this context, the characteristic impedance Z₀ corresponds to the system impedance which is generally 50 Ω. Rather than the ideal profile decreasing uniformly with the frequency, however, the measured frequency-dependent behavior of the line, e.g. the reflection, shows a waviness, the so-called ripple structure, whose amplitude deviations, with respect to the ideal profile, represent the magnitude of the error vector r_{q} and characterize the measurement uncertainty (“uncertainty boundaries”). The amplitude deviations are estimated as a function of the frequency graphically between two neighboring peaks of the ripple structure as so-called peak-to-peak values (FIG. 2) or automatically by means of known software which is frequently implemented in the network analyzer, and the frequency-dependent measurement error is finally determined therefrom for any measurement object (DUT: “device under test”).

In practice, even coaxial lines, which can be produced with high precision, have a characteristic impedance Z₀ which deviates as a function of the frequency from the normalized impedance of 50 Ω. The characteristic impedance Z₀ in coaxial air lines, for example, depends, as described in “Hochfrequenztechnik” [radio frequency technology] by Holger Heuermann, Vieweg-Verlag, ISBN 3-528-03980-9, pages 73 to 77, inter alia strongly on the geometric precision of the outer and inner conductors to one another and on the penetration depth and this, in turn, depends on the frequency.

While in a coaxial line only the penetration depth contributes to the dispersion, in planar conductor systems, such as the coplanar line and micro strip line, considerably greater effects are obtained due to their quasi-TEM character, i.e. due to the emergence of considerably larger transversal components of the magnetic and the electric field in comparison with the emerging longitudinal components, in the case of which the losses via the line are no longer negligible. The transversal and longitudinal field components are defined with respect to the propagation direction of the waves in the conductor. In particular the coplanar lines, which are used in RF test probes for testing electronic devices, also in wafer assemblages (on-wafer measurements), and likewise for calibrating network analyzers, have a behavior of the characteristic impedance, which behavior is dispersive to a high degree, i.e. frequency-dependent, which leads to errors which are not negligible, and which cannot be taken into account by the calibration method itself.

It is on account of their behavior which is dispersive to a high degree, among other things, that these lines which are frequently used in practice cannot be taken into account in classical ripple tests.

Under these conditions, the ripple test provides statements in practice which are just about useful in coaxial measurements. The measurement errors in planar measurements such as on-wafer measurements or even hollow-conductor measurements cannot be estimated in a meaningful way using the known ripple test.

An object of the invention is the method for taking into account the dispersive and, if necessary, also complex properties of waveguides which are used as reference lines in the ripple test. In this way, the measurement error of scattering parameters can be estimated with sufficient accuracy in particular in planar measurements, such as on-wafer measurements. Knowing the general properties of the scattering parameters is in turn useful for assessing measurements and characteristics of devices, components, test arrangements and many more, which in turn forms the basis for the analysis and development of circuits, i.e. the synthesis, optimization and modeling thereof.

The stated method allows that the characteristic impedance of the reference line can be both frequency-dependent and complex, especially in on-wafer measurements. The latter property is based on the losses of a line, which can be high in particular in thin on-wafer lines. Consequently, it is also possible to use reference lines with arbitrary propagation constants. The propagation constants as a complex variable describes the propagation of an electromagnetic wave in the conductor and takes into account by means of the attenuation constant also the attenuation of the line.

Radio-frequency line systems, such as hollow conductors, which are designed for low-loss signal transmission, are, like on-wafer lines, strongly dispersive, so that the abovedescribed classical ripple test was not used for them either. The method which is described in detail below can now be used even for these line systems to estimate measurement errors in a meaningful manner. In general, the characteristic impedance of the reference line can now deviate from the system impedance Z₀ to a virtually arbitrary degree. The possibility of using reference lines with dispersive and complex characteristic impedances also includes the use of the method for measurements with coaxial lines, so that their deviations from the assumed line impedance of 50 Ω can also be taken into account in the error representation.

### DESCRIPTION OF THE INVENTION

The invention will be explained in more detail below using an exemplary embodiment. In the associated drawings:

FIG. 1 shows the representation of an error vector with respect to the vectors of the measured and real reflection parameter,

FIG. 2 shows a graphic determination of a peak-to-peak value,

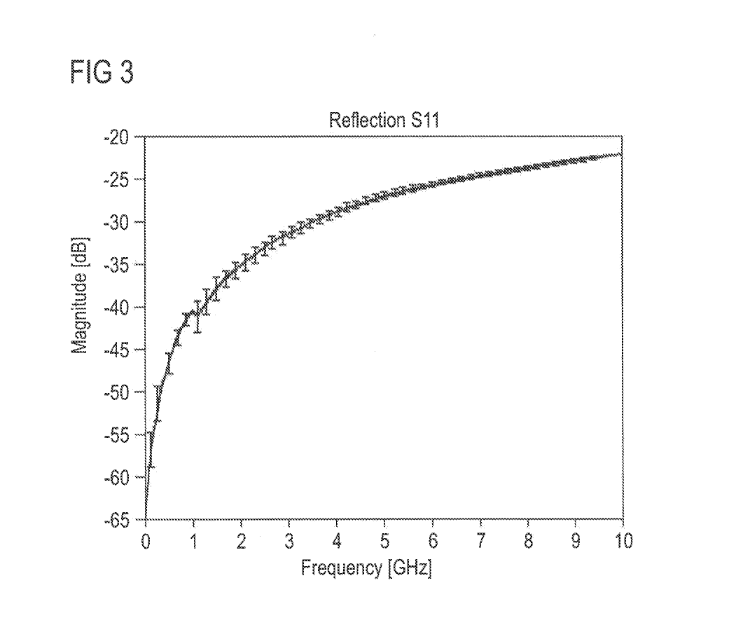

FIG. 3 shows a representation of the magnitude of a reflection parameter as a function of the frequency with error bars and

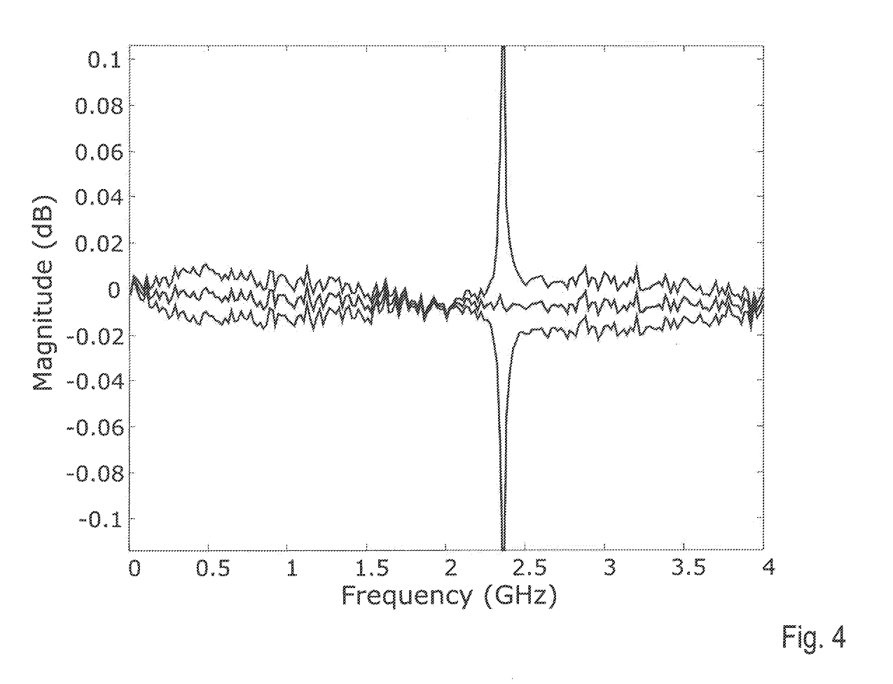

FIG. 4 shows a further representation of the magnitude of a reflection parameter as a function of the frequency with error area.

This method is initially based on the availability of a RF reference line with known dispersive characteristic impedance, which may also be complex. Since the characteristic impedances of all line types, i.e. also of coaxial and planar line types, can be calculated by way of analytical or numerical solutions by means of electromagnetic field simulation or can likewise be characterized by way of measurements, such as the known NIST method (National Institute of Standards and Technology), known reference lines are available for the determination of measurement errors. The measurement of the RF reference line is described, for example, in “Characteristic Impedance Determination Using Propagation Constant Measurement”, R. Marks, D. Williams, IEEE Microwave and Guided Wave Lett., vol. 1, pp 141-143, June 1991. Various methods are known for the electromagnetic field simulation, for example the finite integration (FIT), the finite element analysis, the finite difference time domain method (FDTD) or others. In particular, the finite element analysis can be used to carry out simulations with high accuracy for lossy lines. Various software solutions are available for the simulation to the expert in the field.

First the reflection values of this reference line are measured either as one-port with an open circuit or short circuit, i.e. with a no-loss reactive load as the termination, or as two-port with the reference line as transmission path. Even in the case of measuring the reference line as two-port it is only the input reflection values which are used further. This measurement can be done using a network analyzer which is uncalibrated or calibrated using any, even scalar, calibration method. Scalar calibration refers to such a calibration method in which only the magnitude of the scattering parameters is determined and whose phase, in contrast with the vectorial calibration, is not taken into account.

The determined measurement values of the reflection factors of the reference line are renormalized to the known real and generally dispersive characteristic impedance Z_{L} of the reference line. This is done by converting the S-parameters, which are measured in relation to 50 Ω, to impedance parameters (Z-parameters) as unrelated values by means of the port impedance matrix [Z₅₀] in relation to 50 Ω. These unrelated values are then related to the known characteristic impedance Z_{L} by means of the port impedance matrix [Z_{L}] which is related to the real dispersive characteristic impedance of the reference line. These Z-parameters which are now related are finally converted to S-parameters. The conversions connected with the renormalization, i.e. the conversion of a scattering matrix from one reference impedance to another, are implemented in known RF simulators and the software of network analyzers and can therefore be carried out within the context of the method described here. The equations on which the conversion is based are documented on page 23 in conjunction with page 292 in “Hochfrequenztechnik” by Holger Heuermann, Vieweg-Verlag, ISBN 3-528-03980-9.

From the frequency response of the thus determined renormalized S-parameters, the frequency-dependent error vectors and their magnitude and thus the source match of the network analyzer can be determined, as described for the known ripple test above, by means of the peak-to-peak values or using a computer.

FIG. 3 shows a possible representation of the determined measurement errors. Here, error bars which correspond to the magnitude, determined for discrete frequencies, of the error vector r_{q} are drawn on the frequency response of the magnitude of the reflection parameter S₁₁ for the respective frequency. The error bar can be used to estimate in which area the respective value of the reflection parameter can lie. By way of example, a measurement error which is relatively great in comparison with the measurement errors at higher frequencies can be seen at a peak in the profile of the frequency parameter at approximately 1 GHz. This can have various causes, for example a resonance on account of a length, which is unfavorable for this frequency, of the measured line.

The input impedance of a line can only be measured in a meaningful manner if the line does not have an electric length of n*180° where n=0, 1, 2, . . . , which is related, via the wavelength of the periodic signal, to the geometric length of the line. This is because in the case of said electric length, resonances between the reflected, back-propagating and the forward-propagating wave would occur on account of reflections at the termination of the line. Since the resonance behavior is frequency-dependent for specific mechanical line lengths, it is necessary to use longer lines at lower frequencies. For example, it is possible in measurements over a large frequency range to use, for those frequencies, in which the electric length of a line is exactly n*180 where n=1, 2, 3, . . . , another line with another electric length. In this case the abovedescribed method would have to be carried out for a plurality of reference lines and in each case including characterization of the line, measurement of the reflection and possibly transmission parameters and evaluation of the measurement for each of the lines.

As long as phases and magnitudes of the error vectors are determined by means of a computer, this can be done for every frequency. As a result, the measurement errors cannot just be represented for discrete frequencies in the form of error bars, but as an area around the determined measurement curve (FIG. 4).

1. A method for determining measurement errors in scattering parameter measurements, in particular for giving the measurement accuracy of a scalar or vector network analyzer, which has n measurement ports (n≧1), on the basis of measurements of scattering parameters of a reference line with defined characteristic impedance, comprising the following steps:
determination of the characteristic impedance of the reference line used,
measurement of the reference line either as one-port with a purely reactive termination or as two-port,
renormalization of reflection values of the one-port or of input reflection values of the two-port to the calculated characteristic impedance of the reference line as reference value and
calculation of a source match of the network analyzer from the renormalized reflection values of the reference line.

2. The method as claimed in claim 1, wherein the characteristic impedance of the reference line is determined by way of measurement.

3. The method as claimed in claim 1, wherein the characteristic impedance of the reference line is determined by way of analytical or numerical solutions.

4. The method as claimed in claim 1, wherein the reference line at the one-port is realized as a short circuit.

5. The method as claimed in claim 1, wherein the reference line at the one-port is realized as an open circuit.

6. The method as claimed in claim 1, wherein a plurality of reference lines are used whose characteristic impedances can deviate from one another and the renormalization of the reflection values to the calculated characteristic impedance of the reference line used for measuring the respective reflection values is effected.

7. The method as claimed in claim 1, wherein the characteristic impedance of the reference line to be measured is dispersive and complex.

8. The method as claimed in claim 1, wherein a propagation constant of the reference line to be measured is arbitrary.
